(19) United States
(12) Patent Application Publication
(10) Pub. No.: US 2008/0223287 A1
(43) Pub. Date: Sep. 18, 2008

(54) Plasma enhanced ALD process for copper alloy seed layers

(76) Inventors: Adrien R. Lavoie, Beaverton, OR (US); Juan E. Dominguez, Hillsboro, OR (US)

Correspondence Address: INTEL CORPORATION;c/o INTELLEVATE, LLC, P.O. BOX 52050, MINNEAPOLIS, MN, 55402, US

(21) Appl. No.: 11/724,361

(22) Filed: Mar. 15, 2007

(51) Int. Cl. C30B 23/00

(52) U.S. Cl. 117/94

(57) ABSTRACT

A method of forming a copper alloy seed layer comprises providing a substrate in a reactor, performing a first ALD process to fabricate an alloy metal layer on the substrate, wherein the first ALD process uses an alloy metal precursor selected from a group of specific alloy metal precursors, performing a second ALD process to fabricate a copper metal layer on the alloy metal layer, wherein the second ALD process uses a copper metal precursor selected from a group of specific copper metal precursors, and annealing the alloy metal layer and the copper metal layer to form a graded Cu-alloy layer.

### BACKGROUND

In the manufacture of integrated circuits, copper interconnects are generally formed on a semiconductor substrate using a copper dual damascene process. Such a process begins with a trench being etched into a dielectric layer and filled with a barrier layer, an adhesion layer, and a seed layer. A physical vapor deposition (PVD) process, such as a sputtering process, may be used to deposit a tantalum nitride (TaN) barrier layer and a tantalum (Ta) or ruthenium (Ru) adhesion layer (i.e., a TaN/Ta or TaN/Ru stack) into the trench. The TaN barrier layer prevents copper from diffusing into the underlying dielectric layer. The Ta or Ru adhesion layer is required because the subsequently deposited metals do not readily nucleate on the TaN barrier layer. This may be followed by a PVD sputter process to deposit a copper seed layer into the trench. An electroplating process is then used to fill the trench with copper metal to form the interconnect.

As device dimensions scale down, the aspect ratio of the trench becomes more aggressive as the trench becomes narrower. Due to the line-of-sight deposition process for PVD, this gives rise to issues such as trench overhang of the barrier, adhesion, and seed layers, leading to pinched-off trench and via openings during plating and inadequate gapfill. Additionally, for very thin films (e.g., less than 5 nm thick) on patterned structures, thickness and composition control in PVD is difficult. For instance, for very thin layers the sputter time tends to be low, resulting in different thicknesses on wafer and sidewalls. In addition, early fail electromigration tends to become more of a problematic issue.

One approach to addressing these issues is to reduce the thickness of the TaN/Ta or TaN/Ru stack, which widens the available gap for subsequent metallization. Unfortunately, this is often limited by the non-conformal characteristic of PVD deposition techniques. Accordingly, alternative techniques for depositing the barrier, adhesion, and seed layers are needed.

### BRIEF DESCRIPTION OF THE DRAWINGS

FIG. 1 illustrates a graded Cu-alloy layer in accordance with an implementation of the invention.

FIG. 2 is a method for fabricating a homogenous Cu-alloy layer and a metal interconnect in accordance with an implementation of the invention.

FIG. 3 illustrates the method of FIG. 2.

FIG. 4 is a method 400 for fabricating a graded Cu-alloy layer and a metal interconnect in accordance with an implementation of the invention.

FIG. 5 illustrates the method of FIG. 3.

FIG. 6 is a PEALD process for fabricating the alloy metal layer and the copper metal layer in accordance with an implementation of the invention.

### DETAILED DESCRIPTION

Described herein are methods of fabricating a copper alloy layer that functions as a seed layer for a copper interconnect in an integrated circuit application. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention; however, the order of description should not be construed to imply that these operations are necessarily order dependent. In particular, these operations need not be performed in the order of presentation.

Implementations of the invention provide a copper alloy (Cu-alloy) layer deposited by way of a plasma enhanced atomic layer deposition (PEALD) process that may be used to replace the conventional seed layer used for copper interconnects in integrated circuit applications. The presence of the alloying metal provides resistance to electromigration of the copper metal. The use of a PEALD process overcomes some of the many problems inherent in a PVD process. In some implementations, the Cu-alloy layer may replace the conventional adhesion and barrier layer as well. The alloying metal may include aluminum, manganese, iridium, or magnesium among others. The PEALD process described herein yields a conformal and continuous pure alloy layer by providing more precise control over the thickness of the Cu-alloy layer, by way of the number of PEALD pulses, and over the tailoring or composition of the Cu-alloy layer, by way of modifying the precursors and/or co-reactants used in each PEALD pulse. The PEALD process further allows for the direct addition of dopants to the Cu-alloy layer to improve electromigration and adhesion.

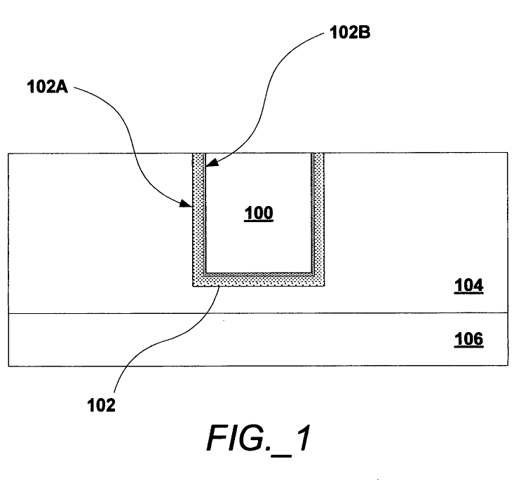

FIG. 1 illustrates a copper interconnect 100 formed within a trench of a dielectric layer 104 upon a substrate 106. The copper interconnect 100 is located within metallization layers of an integrated circuit (IC) die and is used to interconnect transistors and other devices. The substrate 106 may be a portion of a semiconductor wafer. The dielectric layer 104 may be formed using conventional dielectric materials including, but not limited to, oxides such as silicon dioxide (SiO₂) and carbon doped oxide (CDO), silicon nitride, organic polymers such as perfluorocyclobutane (PFCB), and fluorosilicate glass (FSG).

In accordance with an implementation of the invention, a Cu-alloy layer 102 is formed between the copper interconnect 100 and the dielectric layer 104. In some implementations, the Cu-alloy layer 102 may be homogenous across its thickness, in other words, the concentration of copper and the alloy metal may be homogenous throughout the Cu-alloy layer 102. In further implementations, the Cu-alloy layer 102 may be a graded layer where the copper metal has a concentration gradient across the thickness of the Cu-alloy layer 102 and the alloy metal also has a concentration gradient across the thickness of the Cu-alloy layer 102.

FIG. 1 illustrates such a graded Cu-alloy layer 102. For example, a first portion 102A of the graded Cu-alloy layer 102 proximate to the dielectric layer 104 has a high alloy metal concentration and functions to reduce or prevent electromigration of the copper metal. In some implementations, the high alloy metal concentration further serves as a barrier layer to inhibit copper metal from diffusing into the dielectric layer 104. A second portion 102B of the graded Cu-alloy layer 102 proximate to the copper interconnect 100 has a high copper metal concentration to serve as a nucleation site for copper deposition during an electroplating process or an electroless plating process, thereby providing adhesion layer functionality. In implementations of the invention, the graded Cu-alloy layer 102 may have a thickness that ranges from 1 nm to 15 nm.

In accordance with the invention, novel precursors having single and dual metal centers are used in a PEALD process to form the Cu-alloy layer. These precursors include copper metal (Cu) precursors, which are used as the main solute. The precursors also include precursors for aluminum metal (Al), manganese metal (Mn), iridium metal (Ir), or magnesium metal (Mg), which are used as the main solvents. This provides Cu-alloy layers such as Cu—Al, Cu—Mn, Cu—Ir, and Cu—Mg. In further implementations, alternate alloy metals may be chosen.

Copper precursors having single metal centers that may be used in implementations of the invention include, but are not limited to, Cu(I)acetylacetonate, Cu^{II}(acac)₂ (where acac=acetylacetonato), Cu^{II}(tmhd)₂ (where tmhd=tretramethylheptadienyl), Cu(hfac)₂ (where hfac=hexafluoroacetylacetonate), Cu(thd)₂ (where thd=tetrahydrodionato), Cu(I)phenylacetylide, Cu(II)phthalocyanine, pincer-type complexes of Cu⁵, β-diketimine Cu(I) compounds, bisoxazoline complexes of Cu, diimine complexes of Cu, CpCu(CNMe) (where Cp=cyclopentadienyl and Me=methyl), Cp*CuCO, CpCuPR₃ (where R═Me, ethyl(Et), or phenyl(Ph)), CpCu(CSiMe₃)₂, MeCu(PPh₃)₃, CuMe, CuCCH(ethynylcopper), CuCMe₃(methylacetylidecopper), (H₂C═CMeCC) Cu(3-methyl-3-buten-1-ynylcopper), (H₃CCH═CH)₂CuLi (where Li=lithium cation), Me₃SiCCCH₂Cu, Cu₂Cl₂(butadiene), and N,N′-dialkylacetamidinato Cu compounds where the alkyl group that may be used includes, but is not limited to, isopropyl (iPr), sec-butyl, n-butyl, Me, Et, and linear propyl (n-Pr).

Aluminum precursors having single metal centers that may be used in implementations of the invention include, but are not limited to, aluminium s-butoxide, trimethylaluminum (AlMe₃ or TMA), triethylaluminum (AlEt₃ or TEA), di-i-butylaluminum chloride, di-i-butylaluminum hydride, diethylaluminum chloride, tri-i-butylaluminum, triethyl(tri-sec-butoxy)dialuminum, and 1-methylPyrrolidineAlane aluminum.

Manganese precursors having single metal centers that may be used in implementations of the invention include, but are not limited to, CpMn(CO)₃, β-diketimine Mn compounds, nitrosyl Mn (e.g., (pentadienyl)₃Mn₂(NO)₈).

Iridium precursors having single metal centers that may be used in implementations of the invention include, but are not limited to, Ir(CO)₂X₄ where X═Cl or Br, Irl(CO)₃, HIr(CO)₄, CpIr(CO)₂, pyrrolyl-Ir—(CO)₂—Cl, and ligand variations thereof including, but not limited to, allyls, cyclohexadienyl, and pentamethylCp.

In implementations of the invention, dual metal center precursors that may be used are organometallic compounds that include both copper and another metal such as Al, Mn, Ir, or Mg. In further implementations, dual metal center precursors may include copper with a metal other than Al, Mn, Ir, or Mg. Dual metal center precursors include, but are not limited to, [(CO)₅Mn(C₆H₅)₂Cu]₂, [CuMn₂R(alkyl)(NCN)₂], CpCu(CH₃)₂Al(CH₃)₂, and CpCuMe-TMA adducts (where TMA=trimethylaluminum).

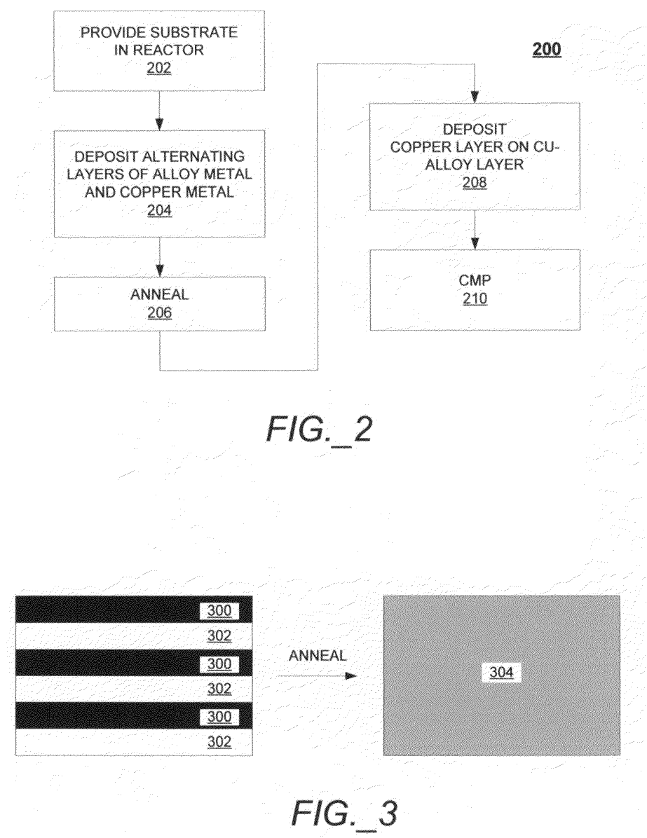

FIG. 2 is a method 200 for fabricating a homogenous Cu-alloy layer and a metal interconnect in accordance with an implementation of the invention. The method 200 begins by providing a semiconductor substrate onto which the Cu-alloy layer and the metal interconnect may be formed (process 202 of FIG. 2). The semiconductor substrate may be formed using a bulk silicon or a silicon-on-insulator substructure. In other implementations, the substrate may be formed using alternate materials, which may or may not be combined with silicon, that include but are not limited to germanium, indium antimonide, lead telluride, indium arsenide, indium phosphide, gallium arsenide, gallium antimonide, or other Group III-V materials. Although a few examples of materials from which the semiconductor substrate may be formed are described here, any material that may serve as a foundation upon which a semiconductor device may be built falls within the spirit and scope of the present invention.

The substrate has at least one dielectric layer deposited on its surface. The dielectric layer may be formed using materials known for the applicability in dielectric layers for integrated circuit structures, such as low-k dielectric materials. Such dielectric materials include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The dielectric layer may include pores or other voids to further reduce its dielectric constant. The dielectric layer may include one or more trenches and/or vias within which the Cu-alloy layer will be deposited and the metal interconnect will be formed. The trenches and/or vias may be patterned using conventional wet or dry etch techniques that are known in the art.

In some implementations, the substrate may further include a barrier layer and an adhesion layer. These layers may be optional depending on the specific Cu-alloy layer being formed. For instance, if a Cu-Mn alloy layer is being formed, the barrier layer and the adhesion layer may be eliminated. This is because the Cu—Mn alloy layer may provide the barrier functionality as well as the adhesion/seed functionality. If, however, a Cu—Al alloy layer is being formed, a separate barrier layer is required. In this instance, the adhesion layer may be eliminated in some implementations. In further implementations the adhesion layer may still be used.

The substrate may be housed in a reactor in preparation for a PEALD process. Within the reactor, using the above listed metal precursors, alternating layers of the alloy metal and copper metal are deposited upon the substrate using a PEALD process (204). The alternating layers are illustrated in FIG. 3, where layers of copper metal 300 alternate with layers of an alloy metal 302 to form a stack of layers. If the dual metal center precursors described above are used, the alloy metal layers 302 may include copper metal in addition to the alloy metal. The thickness of each of these layers may range from 0.5 nm to 20 nm.

After the alloy metal layers and copper metal layers have been deposited, the stack of alternating metal layers may be annealed to combine the layers into one homogenous Cu-alloy layer (206). This is also shown in Figure 3 as homogenous Cu-alloy layer 304. The anneal takes place at a temperature that may range from 50° C. to 400° C. for a time duration that may last from 5 seconds to 1200 seconds. The anneal may take place in an oxygen free ambient atmosphere, such as forming gas or a pure inert gas. During the anneal, the alloy metal layers 302 and the copper metal layers 300 intermix or diffuse together to merge and form the single homogenous Cu-alloy layer 304.

Following the fabrication of the homogenous Cu-alloy layer 304, the substrate may be transferred to a reactor containing a plating bath and a plating process may be carried out to deposit a metal layer, such as a copper layer, over the homogenous Cu-alloy layer (208). The copper layer fills the trench to form the copper interconnect. In some implementations, the plating bath is an electroplating bath and the plating process is an electroplating process. In other implementations, the plating bath is an electroless plating bath and the plating process is an electroless plating process. In further implementations, alternate copper deposition processes may be used. Finally, a chemical mechanical polishing (CMP) process may be used to planarize the deposited copper metal and finalize the copper interconnect structure (210).

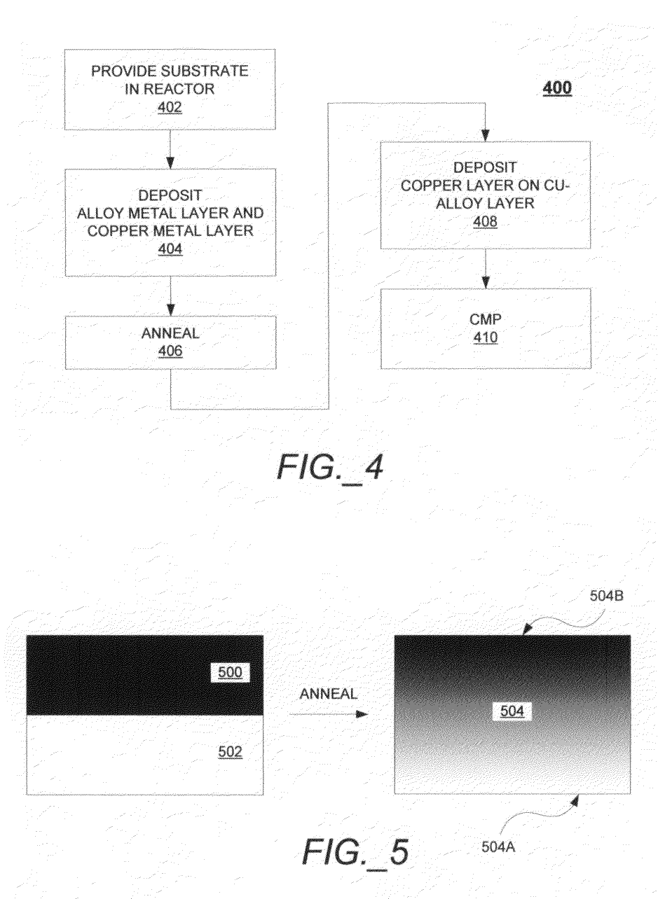

FIG. 4 is a method 400 for fabricating a graded Cu-alloy layer and a metal interconnect in accordance with an implementation of the invention. The method 400 begins by providing a semiconductor substrate onto which the graded Cu-alloy layer and the metal interconnect may be formed (402). The substrate has at least one dielectric layer deposited on its surface that includes a trench in which the metal interconnect will be formed. In some implementations, the substrate may further include a barrier layer and an adhesion layer. The substrate may be housed in a reactor in preparation for a PEALD process.

Within the reactor, using the above listed metal precursors, a single alloy metal layer and a single copper metal layer are deposited upon the substrate using a PEALD process (404). The two layers are illustrated in FIG. 5, where a copper metal layer 500 is formed atop an alloy metal layer 502. If a dual metal center precursor is used, the alloy metal layer 502 may include copper metal in addition to the alloy metal. The thickness of each of these layers may range from 5 nm to 20 nm.

After the alloy metal layer and copper metal layer have been deposited, the layers may be annealed to combine the layers into one graded Cu-alloy layer (406). This is also shown in FIG. 5 as graded Cu-alloy layer 504. The anneal takes place at a temperature that may range from 50° C. to 400° C. for a time duration that may last from 5 seconds to 1200 seconds. During the anneal, a portion of the alloy metal diffuses into the copper metal layer and a portion of the copper metal diffuses into the alloy metal layer, thereby merging the layers into a single Cu-alloy layer 504 and producing graded concentrations of alloy metal and copper metal across the thickness of the Cu-alloy layer. The alloy metal concentration is highest at a first portion 504A of the Cu-alloy layer 504 adjacent to the substrate. The alloy metal concentration decreases to substantially zero at a second portion 504B of the Cu-alloy layer 504 where the metal interconnect is deposited. Contrary to this, the copper metal concentration is highest at the second portion 504B of the Cu-alloy layer 504 where the metal interconnect is deposited and decreases until it reaches the first portion 504A of the Cu-alloy layer 504 adjacent to the substrate.

Following the fabrication of the graded Cu-alloy layer 504, the substrate may be transferred to a reactor containing a plating bath and a plating process may be carried out to deposit a metal layer, such as a copper layer, over the graded Cu-alloy layer (408). Again, an electroplating process or an electroless plating process is commonly used. Finally, a CMP process may be used to planarize the deposited copper metal and finalize the copper interconnect structure (410).

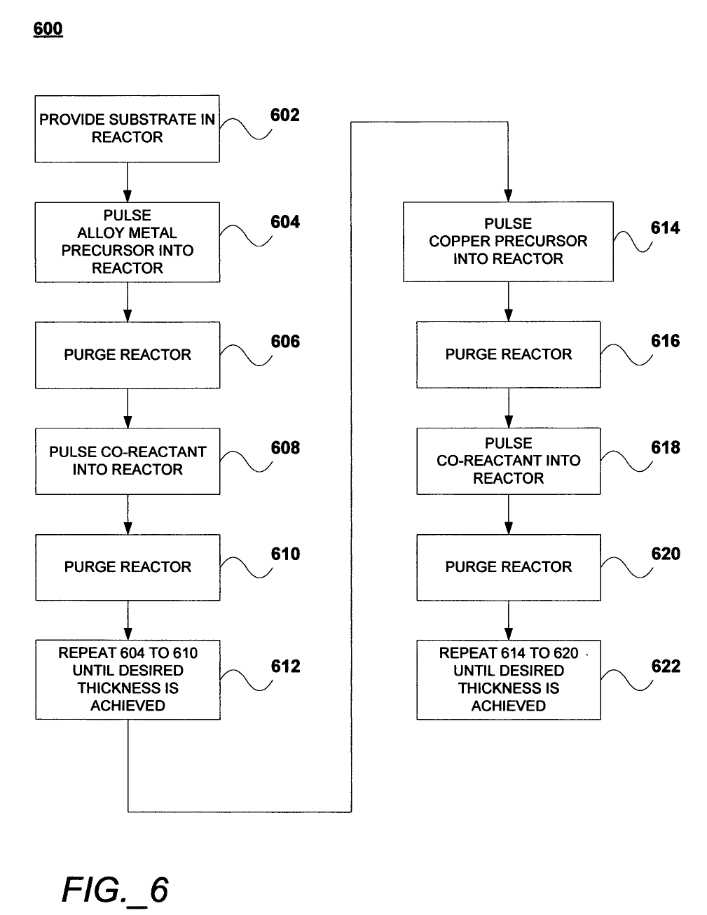

FIG. 6 is a specific PEALD process 600 for fabricating the alloy metal layer and the copper metal layer in accordance with an implementation of the invention. The method 600 may be used to form two layers that are annealed to form a graded layer, as shown in FIG. 5, or the method 600 may be repeated to form an alternating stack of layers that are annealed to form a homogenous layer, as shown in FIG. 3.

The method begins with a semiconductor substrate housed in an PEALD reactor (602). The substrate may be heated within the reactor to a temperature between around 25° C. and around 250° C. The pressure within the reactor may range from 0.01 Torr to 3.0 Torr.

One or more ALD process cycles are then used to deposit an alloy metal layer using at least one of the above listed single or dual metal center precursors that include the desired alloy metal. This process cycle usually begins with at least one pulse of the selected alloy metal precursor that is introduced into the reactor (604). In various implementations of the invention, the following process parameters may be used for the alloy metal precursor pulse. The alloy metal precursor pulse may have a duration that ranges from around 0.5 second to around 10 seconds with a flow rate of up to 10 standard liters per minute (SLM). The specific number of alloy metal pulses may range from 1 pulse to 200 pulses or more depending on the desired thickness of the alloy metal layer. The alloy metal precursor temperature may be between around 60° C. and 250° C. The vaporizer temperature may be around 60° C. to around 250° C.

A heated carrier gas may be employed to move the alloy metal precursor, with a temperature that generally ranges from around 50° C. to around 200° C. Carrier gases that may be used here include, but are not limited to, argon (Ar), xenon (Xe), helium (He), hydrogen (H₂), nitrogen (N₂), forming gas, or a mixture of these gases. The flow rate of the carrier gas may range from around 100 SCCM to around 300 SCCM.

The precursor delivery line into the reactor may be heated to a temperature that ranges from around 60° C. to around 250° C., or alternately, to a temperature that is at least 25° C. hotter than the volatile precursor flow temperature within the delivery line to avoid condensation of the precursor. Generally the delivery line temperature may be around 100° C. to around 180° C. Before discharge, the delivery line pressure may be set to around 0 to 5 psi, the orifice may be between 0.1 mm and 1.0 mm in diameter, and the charge pulse may be between 0.5 seconds and 5 seconds. The equilibration time with the valves closed may be 0.5 seconds to 5 seconds and the discharge pulse may be 0.5 seconds to 5 seconds.

An RF energy source may be during the alloy metal precursor pulse at a power that ranges from 5W to 200W and at a frequency of 13.56 MHz, 27 MHz, or 60 MHz. It should be noted that the scope of the invention includes any possible set of process parameters that may be used to carry out the implementations of the invention described herein.

After the at least one pulse of the alloy metal precursor, the reactor may be purged (606). The purge gas may be an inert gas such as Ar, Xe, N₂, He, or forming gas and the duration of the purge may range from 0.1 seconds to 60 seconds, depending on the PEALD reactor configurations and other deposition conditions. In most implementations of the invention, the purge may range from 0.5 seconds to 10 seconds.

In accordance with an implementation of the invention, at least one pulse of a co-reactant is introduced into the reactor to react with the alloy metal precursor (608). In some implementations the co-reactant may be hydrogen, a hydrogen plasma, a hydrogen/nitrogen plasma, methane, silane, B₂H₆, or GeH₄. Conventional process parameters may be used for the co-reactant pulse. For instance, in implementations of the invention, the process parameters for the co-reactant pulse include, but are not limited to, a co-reactant pulse duration of between around 0.5 seconds and 10 seconds, a co-reactant flow rate of up to 10 SLM, a reactor pressure between around 0.05 Torr and 3.0 Torr, a co-reactant temperature between around 80° C. and 200° C., a substrate temperature between around 100° C. and around 400° C., and an RF energy source that may be applied at a power that ranges from 5W to 200W and at a frequency of 13.56 MHz, 27 MHz, or 60 MHz. It should be noted that the scope of the invention includes any possible set of process parameters that may be used to carry out the implementations of the invention described herein.

After the at least one pulse of the co-reactant, the reactor may again be purged (610). The purge gas may be an inert gas such as Ar, Xe, N₂, He, or forming gas and the duration of the purge may range from 0.1 seconds to 60 seconds, depending on the PEALD reactor configurations and other deposition conditions. In most implementations of the invention, the purge may range from 0.5 seconds to 10 seconds.

The above processes result in the formation of an alloy metal layer on the substrate. If a single metal center alloy precursor was used, then the alloy metal layer contains just the alloy metal (e.g., Al, Mn, Sn, Ir, or Mg). If a dual metal center precursor was used, the alloy metal layer contains both the alloy metal (e.g., Al, Mn, Sn, Ir, or Mg) and copper metal. Therefore, the alloy metal layer 302 shown in FIG. 3 or the alloy metal layer 502 shown in FIG. 5 may contain just an alloy metal or it may contain both an alloy metal and copper metal. Because a PEALD process is used, if the alloy layer has not yet reached a desired thickness, the above processes may be repeated as necessary until the desired thickness is achieved (612).

Next, one or more ALD process cycles are used to deposit a copper metal layer atop the alloy metal layer. The copper metal process cycle usually begins with at least one pulse of a copper precursor that is introduced into the reactor (614). The copper metal precursor selected here may be any of the single metal center copper precursors described above. In various implementations of the invention, the process parameters provided above may be used for this copper metal precursor pulse. For instance, the copper precursor pulse may range from around 0.5 second to around 10 seconds with a flow rate of up to 10 SLM, with the specific number of copper precursor pulses ranging from 1 pulse to 200 pulses or more depending on the desired thickness of the copper metal layer.

After the at least one pulse of the copper precursor, the reactor may be purged (616). Then at least one pulse of a co-reactant may be introduced into the reactor to react with the copper precursor (618). The co-reactants provided above, including the plasma co-reactants, may be used here with the process parameters provided. A reactor purge may follow the co-reactant pulse (620).

The above processes result in the formation of a copper metal layer on the alloy metal layer. Again, since this is a PEALD process, if the copper metal layer has not yet reached a desired thickness, the above processes may be repeated as necessary until the desired thickness is achieved (622).

In implementations of the invention where a graded Cu-alloy layer is being formed, the process 600 is complete after one alloy metal layer and one copper metal layer are formed. The alloy metal layer and the copper metal layer may be annealed to form a graded Cu-alloy layer as described in FIG. 5. In alternate implementations where several alternating layers are used to form a homogenous Cu-alloy layer, as shown in FIG. 3, the process 600 may be repeated as necessary. The stack of alternating alloy metal layers and copper metal layers may then be annealed to form a homogenous Cu-alloy layer as described in FIG. 3.

In implementations where a plasma is used as a co-reactant, process parameters that may be used include a flow rate of around 200 SCCM to around 600 SCCM. The plasma may be pulsed into the reactor with a pulse duration of around 0.5 seconds to around 4.0 seconds, with a pulse duration of around 1 to 4 seconds often being used. The plasma power may range from around 20W to around 500W and will generally range from around 60W to around 200W. A carrier gas such as He, Ar, or Xe may be used to introduce the plasma. A chuck upon which the semiconductor substrate is mounted may be biased and capacitively-coupled. In further implementations of the invention, the plasma may be used to activate a surface before the precursor pulse, to regenerate the surface after a co-reactant pulse, or to activate the precursor and/or co-reactant to obtain low temperature depositions. The use of a plasma therefore tends to yield smooth layers.

In further implementations of the invention, the Cu-alloy layer may be further tailored to have a specific composition by manipulating process parameters during the deposition process. Process parameters that may be manipulated to establish a copper metal concentration gradient and/or an alloy metal concentration gradient within the Cu-alloy layer include, but are not limited to, the specific precursors that are used in each process cycle, how long each precursor is flowed into the reactor during a process cycle, the precursor concentration and flow rate during each process cycle, the co-reactant used, how long each co-reactant is flowed into the reactor during a process cycle, the co-reactant concentration and flow rate during each process cycle, the sequence or order of the precursor and co-reactant, the plasma energy applied, the substrate temperature, the pressure within the reaction chamber, and the carrier gas composition. Furthermore, changing the parameters of each individual process cycle, or groups of successive process cycles, may also be used to tailor the Cu-alloy layer.

In implementations of the invention, the Cu-alloy layer may be used to prevent copper dewetting from dielectric materials or metallic substrates as well as to improve adhesion between the copper layer and the substrate. The use of an alloying metal can also decrease the deposition temperature used and thereby generate smoother films.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize. The scope of the invention is to be determined entirely by the following claims, which are to be construed in accordance with established doctrines of claim interpretation.

1. A method comprising:
providing a substrate in a reactor;
performing a first ALD process to fabricate an alloy metal layer on the substrate, wherein the first ALD process uses an alloy metal precursor selected from the group consisting of aluminium s-butoxide, trimethylaluminum, triethylaluminum, di-i-butylaluminum chloride, di-i-butylaluminum hydride, diethylaluminum chloride, tri-i-butylaluminum, triethyl(tri-sec-butoxy)dialuminum, 1-methylPyrrolidineAlane aluminum, CpMn(CO)₃, β-diketimine Mn compounds, nitrosyl Mn, (pentadienyl)₃Mn₂(NO)₈), Ir(CO)₂Cl₄, Ir(CO)₂Br₄, IrI(CO)₃, HIr(CO)₄, CpIr(CO)₂, pyrrolyl-Ir—(CO)₂—Cl, [(CO)₅Mn(C₆H₅)₂Cu]₂, [CuMn₂R(alkyl)(NCN)₂], CpCu(CH₃)₂Al(CH₃)₂, CpCuMe-TMA adducts, and dual metal center precursors that include copper and at least one of Al, Mn, Ir, or Mg;
performing a second ALD process to fabricate a copper metal layer on the alloy metal layer, wherein the second ALD process uses a copper metal precursor selected from the group consisting of Cu(I)acetylacetonate, Cu^{II}(acac)₂, Cu^{II}(tmhd)₂, Cu(hfac)₂, Cu(thd)₂, Cu(I)phenylacetylide, Cu(II)phthalocyanine, pincer-type complexes of Cu⁵, β-diketimine Cu(I) compounds, bisoxazoline complexes of Cu, diimine complexes of Cu, CpCu(CNMe), Cp*CuCO, CpCuPMe₃, CpCuPEt₃, CpCuPPh₃, CpCu(CSiMe₃)₂, MeCu(PPh₃)₃, CuMe, CuCCH(ethynylcopper), CuCMe₃(methylacetylidecopper), (H₂C═CMeCC)Cu(3-methyl-3-buten-1-ynylcopper), (H₃CCH═CH)₂CuLi, Me₃SiCCCH₂Cu, Cu₂Cl₂(butadiene), and N,N′-dialkylacetamidinato Cu compounds; and
annealing the alloy metal layer and the copper metal layer to form a graded Cu-alloy layer.

2. The method of claim 1, wherein the first ALD process comprises:
pulsing the alloy metal precursor into the reactor proximate to the substrate;
purging the reactor after the alloy metal precursor pulse;
pulsing a co-reactant into the reactor proximate to the substrate; and
purging the reactor after the co-reactant pulse.

3. The method of claim 1, wherein the second ALD process comprises:
pulsing the copper metal precursor into the reactor proximate to the substrate;
purging the reactor after the copper metal precursor pulse;
pulsing a co-reactant into the reactor proximate to the substrate; and
purging the reactor after the co-reactant pulse.

4. The method of claim 2, wherein the co-reactant comprises at least one of hydrogen, a hydrogen plasma, a hydrogen/nitrogen plasma, methane, silane, B₂H₆, or GeH₄.

5. The method of claim 3, wherein the co-reactant comprises at least one of hydrogen, a hydrogen plasma, a hydrogen/nitrogen plasma, methane, silane, B₂H₆, or GeH₄.

6. The method of claim 1, further comprising repeating the first ALD process until the alloy metal layer has reached a desired thickness.

7. The method of claim 1, further comprising repeating the second ALD process until the copper metal layer has reached a desired thickness.

8. The method of claim 1, wherein the annealing process occurs at a temperature between 50° C. and 400° C. for a time duration between 5 seconds and 1200 seconds.

9. A method comprising:
providing a substrate in a reactor;
depositing a stack of alternating alloy metal and copper metal layers on the substrate,
wherein the alloy metal layers are fabricated using a first ALD process that uses an alloy precursor selected from the group consisting of aluminium s-butoxide, trimethylaluminum, triethylaluminum, di-i-butylaluminum chloride, di-i-butylaluminum hydride, diethylaluminum chloride, tri-i-butylaluminum, triethyl(tri-sec-butoxy)dialuminum, 1-methylPyrrolidineAlane aluminum, CpMn (CO)₃, β-diketimine Mn compounds, nitrosyl Mn, (pentadienyl)₃Mn₂(NO)₈), Ir(CO)₂Cl₄, Ir(CO)₂Br₄, IrI(CO)₃, HIr(CO)₄, CpIr(CO)₂, pyrrolyl-Ir—(CO)₂—Cl, [(CO)₅Mn(C₆HS)₂Cu]₂, [CuMn₂R(alkyl)(NCN)₂], CpCu(CH₃)₂Al(CH₃)₂, CpCuMe-TMA adducts, and dual metal center precursors that include copper and at least one of Al, Mn, Ir, or Mg, and
wherein the copper metal layers are fabricated using a second ALD process that uses a copper precursor selected from the group consisting of Cu(I)acetylacetonate, Cu^{II}(acac)₂, CuI(tmhd)₂, Cu(hfac)₂, Cu(thd)₂, Cu(I)phenylacetylide, Cu(II)phthalocyanine, pincer-type complexes of Cu⁵, β-diketimine Cu(I) compounds, bisoxazoline complexes of Cu, diimine complexes of Cu, CpCu(CNMe), Cp*CuCO, CpCuPMe₃, CpCuPEt₃, CpCuPPh₃, CpCu(CSiMe₃)₂, MeCu(PPh₃)₃, CuMe, CuCCH(ethynylcopper), CuCMe₃(methylacetylidecopper), (H₂C═CMeCC)Cu(3-methyl-3-buten-1-ynylcopper), (H₃CCH═CH)₂CuLi, Me₃SiCCCH₂Cu, Cu₂Cl₂(butadiene), and N,N′-dialkylacetamidinato Cu compounds; and
annealing the stack to form a homogenous Cu-alloy layer.

10. The method of claim 9, wherein the first ALD process comprises:
pulsing the alloy metal precursor into the reactor proximate to the substrate;
purging the reactor after the alloy metal precursor pulse;
pulsing a co-reactant into the reactor proximate to the substrate; and
purging the reactor after the co-reactant pulse.

11. The method of claim 9, wherein the second ALD process comprises:
pulsing the copper metal precursor into the reactor proximate to the substrate;
purging the reactor after the copper metal precursor pulse;
pulsing a co-reactant into the reactor proximate to the substrate; and
purging the reactor after the co-reactant pulse.

12. The method of claim 10, wherein the co-reactant comprises at least one of hydrogen, a hydrogen plasma, a hydrogen/nitrogen plasma, methane, silane, B₂H₆, or GeH₄.

13. The method of claim 1 1, wherein the co-reactant comprises at least one of hydrogen, a hydrogen plasma, a hydrogen/nitrogen plasma, methane, silane, B₂H_{6,} or GeH₄.

14. The method of claim 9, further comprising repeating the first ALD process until the alloy metal layer has reached a desired thickness.

15. The method of claim 9, further comprising repeating the second ALD process until the copper metal layer has reached a desired thickness.

16. The method of claim 9, wherein the annealing process occurs at a temperature between 50° C. and 400° C. for a time duration between 5 seconds and 1200 seconds.
